(19) United States
(12) Patent Application Publication
(10) Pub. No.: US 2004/0181740 A1
(43) Pub. Date: Sep. 16, 2004

(54) Communicating method, transmitting apparatus, receiving apparatus, and communicating system including them

(76) Inventors: Tomonobu Tomaru, Nara (JP); Yoshihiro Ohtani, Kyoto (JP)

Correspondence Address: BIRCH STEWART KOLASCH & BIRCH, PO BOX 747, FALLS CHURCH, VA, 22040-0747, US

(21) Appl. No.: 10/477,103

(22) PCT Filed: Apr. 24, 2002
(86) PCT No.: PCT/JP02/04105

(30) Foreign Application Priority Data
May 11, 2001 (JP) 2001-142389

(51) Int. Cl. H03M 13/00

(52) U.S. Cl. 714/776

(57) ABSTRACT

Data packets (P(1)) to (P(9)) transmitted from a root node include, for example, data blocks (B(101)) each including an error-correction code. If a data packet (P(3)) is received from the root node, and data error of a data block (B(302)), etc. is impossible, a leaf node transmits to the root node a retransmission request for it and block count information (CYCLE5; including a header H making up an independent block) specifying the number of next new transmission data blocks (compression ratio). The root node retransmits requested blocks in a next data packet (P(4)), transmits new blocks (B(401)), (B(402)), and remaining data blocks (B(403)), (B(404)) in a next data packet (P(5)). In this manner, new data is compressed, and the number of retransmissions of data blocks is increased. Thus, data transmission is better ensured while maintaining real time data transmission.

### TECHNICAL FIELD

The present invention relates to a communications method and system for retransmitting data in wireless communications, as well as transmitter and receiver devices which make part of the communications system.

### BACKGROUND ART

Typical error recovery methods include ARQ (Automatic Retransmission Request) and FEC (Forward Error Correction). In ARQ, a transmitting station transmits a packet including an added redundant code to a receiving station. The receiving station then performs error detection according to the redundant code, and if there are any errors, transmits a request for a packet retransmission to the transmitting station. The transmitting station then retransmits the packet.

In FEC, the receiving station performs error correction based on a redundant code added by the transmitting station.

Two-Step Adaptive Error Recovery Scheme for Video Transmission over Wireless Networks, Daji Qiao and Kang G. Shin, IEEE INFOCOM 2000 (“document 1”) proposes another example, hybrid ARQ where ARQ is hybridized with FEC.

According to the scheme, the transmitting station adds a block error-correction code (RS code) to a packet before sending it to the receiving station which performs error correction based on the RS code. The receiving station transmits either a positive ACK or a negative ACK to the transmitting station in accordance with a result of the error correction. The transmitting station retransmits the packet if has received a negative ACK or no ACK at all, positive or negative, during a timeout interval.

In some situations, the bit error rate is so high that the use of an error-correction code with high correction capability does not help much to practically achieve an error-free environment without retransmission. When this is the case, a process based on a connected code of a convolution code and a block code or interleaving is generally needed to achieve the environment. This leads to problems of increased circuit scale and a need for a huge buffer at both the transmitting station and the receiving station.

Document 1 describes a technique whereby if the receiving station has failed in an error correction process, the receiving station sends the transmitting station a retransmission request in accordance with which the transmitting station retransmits data packet by packet.

The technique utilizes long packets, each 800 to 900 byte long, and requires a broad bandwidth for a single retransmission. Repeated retransmissions are necessary, especially, in poor communication conditions, but the number of repetitions is limited by the broad bandwidth required by the long packets (packets with long packet lengths).

Besides, if the receiving station reproduces video, audio, or the like from associated data immediately after its reception, the transmitting station needs to transmit data within a designated time that allows for consecutive reproduction (to perform a real-time transmission or transfer). However, the transmitting station may fail to complete the data transmission in a designated time, because of the limited number of possible retransmissions in the long-packet transmission. The failure may cause an unwelcome result, such as disrupted or interrupted video/audio reproduction, at the receiving station.

In addition, long packet lengths make the superimposition of block noise on transmitted data more likely, which may drastically decrease reproduction quality of video, etc.

### DISCLOSURE OF INVENTION

The present invention has an objective to provide a communications method, a transmitter device, a receiver device, and a communications system with improved data transmission reliability while ensuring the real-time nature of the data transmission.

To solve the problems and thus achieve the objective, a communications method in accordance with the present invention is a communications method where a data packet transmitted from a transmitting station is received at a receiving station using a data packet, in which data is divided into one or more blocks, containing data blocks each of which has an error-correction code, and is characterized in that:

the receiving station transmits a retransmission request for an error-uncorrectable data block and transmits a block count alteration request which changes a number of data blocks to be newly transmitted in accordance with good/poor communications conditions on the basis of a result of error correction; and

the transmitting station transmits data blocks to be retransmitted in accordance with a retransmission request and new data blocks changed in accordance with a block count alteration request in the same data packet.

The transmitter device according to the present invention, to solve the problems, is a transmitter device for transmitting to a receiver device a data packet, in which data is divided into one or more blocks, containing data blocks each of which has an error-correction code, and is characterized in that:

when having received a retransmission request for error-uncorrectable data blocks and a block count alteration request which changes a number of data blocks to be newly transmitted in accordance with good/poor communications conditions, transmitted from the receiver device, the transmitter device transmits data blocks to be retransmitted in accordance with a retransmission request and new data blocks changed in accordance with a block count alteration request in the same data packet.

According to the arrangement, a transmitting station (transmitter device) transmits a data packet containing one or more data blocks to a receiving station (receiver device); the receiving station therefore performs separate error correction on each data block upon receipt of the data packet. When there are error-uncorrectable data blocks, the receiving station transmits a retransmission request requesting the transmitting station to retransmit the data blocks. Besides, when communications conditions deteriorate due to obstruction and environment, if the receiving station determines on the basis of a result of error correction that communications conditions have deteriorated, the receiving station transmits a block count alteration request to restrict the number of data blocks to be newly transmitted. Meanwhile, as the transmitting station receives the retransmission request and the block count alteration request, the transmitting station transmits data blocks in accordance with it and data blocks changed (reduced) in accordance with the block count alteration request in the same data packet.

Besides, when communications conditions have improved, if the receiving station determines on the basis of a result of error correction that communications conditions are good, the receiving station transmits a block count alteration request to restore the number of data blocks to be newly transmitted to a previous value. Meanwhile, as the transmitting station receives a retransmission request and its block count alteration request, the transmitting station transmits data blocks in accordance with it and data blocks changed (increased) in accordance with the block count alteration request in the same data packet.

In this manner, when communications conditions have deteriorated, newly transmitted data is more compressed. Although quality of reproduced data may fall, more data blocks can be retransmitted. This greatly reduces missing video or similar real time data and restrains occurrences of block noise. In contrast, when communications conditions have improved, newly transmitted data is less compressed, and new data blocks can be transmitted without lowering quality of reproduced data.

Additional objects, advantages and novel features of the invention will be set forth in part in the description which follows, and in part will become apparent to those skilled in the art upon examination of the following or may be learned by practice of the invention.

### BRIEF DESCRIPTION OF DRAWINGS

FIG. 1 is an explanatory drawing showing a frame structure for each packet exchanged between a root node and multiple leaf nodes in a communications system which is an embodiment of the present invention.

FIG. 2 is an explanatory drawing showing another frame structure for each packet exchanged between a root node and multiple leaf nodes in a communications system which is an embodiment of the present invention.

FIG. 3 is a block diagram showing an arrangement of the communications system.

FIG. 4 is a block diagram showing an arrangement for the root node.

FIG. 5 is a block diagram showing an arrangement for the leaf node.

FIG. 6 is an explanatory drawing showing a format for a data packet transmitted from the root node.

FIG. 7 is an explanatory drawing showing a format for a retransmission request packet transmitted from the leaf node.

FIG. 8 is an explanatory drawing showing a format for another retransmission request packet transmitted from the leaf node.

FIG. 9 is a flow chart depicting an operational procedure for the communications system.

### BEST MODE FOR CARRYING OUT THE INVENTION

The following will describe the present invention in more detail by way of embodiments. The present invention is by no means limited by the embodiments.

[Embodiment 1]

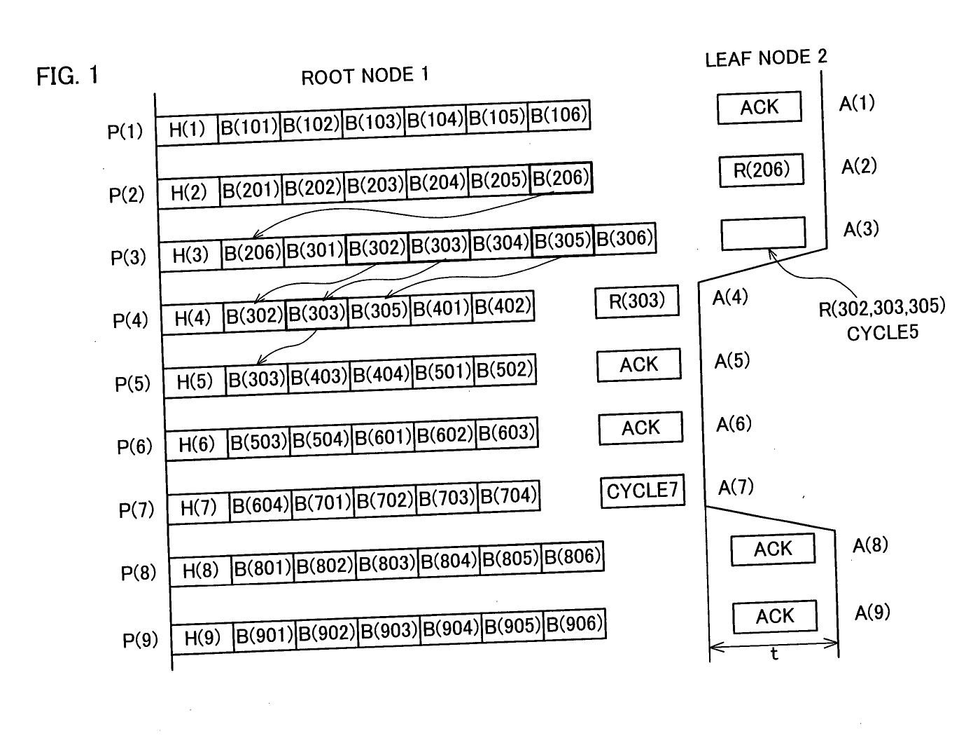

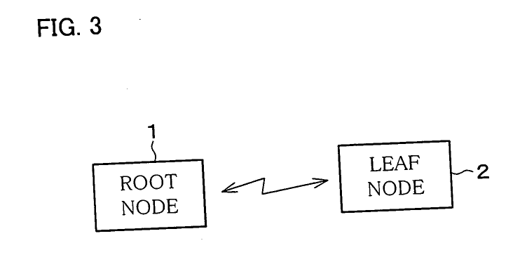

A communications system of the present embodiment includes a root node 1 and a leaf node 2 which are linked with each other by wireless communications (radio waves, infrared waves, or the like) as shown in FIG. 3. The root node 1 transmits video and audio data supplied in real time from a video camera, television, etc. to leaf nodes 2 in the form of data packets made up of multiple data blocks. Each data block (e.g., B(101) to B(106) in FIG. 1) includes coded error-correcting data.

The root node 1 as a transmitter device includes a data coding section 11, a data storage device 12, a transmission packet generating section 13, an error-correction coding section 14, a data transmitting section 15, a retransmission request packet receiving section 16, and a retransmission request packet analyzing section 17.

The data coding section 11 divides, for output, new input data from a video camera or the like into predetermined blocks, so that the error-correction coding section 14 can code the data blocks one by one (detailed later). Besides, the data coding section 11 compresses the new input data, where necessary, in accordance with compression information from the retransmission request packet analyzing section 17 (detailed later).

Specifically, the data coding section 11 receives the number of data blocks to be transmitted in a single data packet (“block count information”) as compression information and calculates an appropriate data compression ratio from the number of data blocks, so as to compresses data according to the data compression ratio. The data compression ratio is, for example, calculated by providing the root node 1 with a table showing a correspondence between numbers of data blocks and data compression ratios in advance.

Besides, in the compression of the new input data, the data coding section 11 changes the compression ratio for the new input data as it receives the block count information, so as to change a cycle period in accordance with the block count information. For example, when the cycle period is made shorter, a new data block group cannot be possibly transmitted in a single data packet, depending on the number of retransmitted data blocks. When this is the case, the transmission packet generating section 13 selects a data block so that some new data blocks are transmitted in a next data packet. Specific description will be given later in example 1.

The data storage device 12 as data block storage means has a memory and related circuits (e.g., a memory control circuit) to temporarily store data supplied from the data coding section 11. The data storage device 12 includes a control circuit for readout of desired data blocks from the memory on the basis of retransmission request information obtained through analysis by the retransmission request packet analyzing section 17, to output data in a retransmission-requested data block. Besides, the data storage device 12 reads the data block in accordance with a retransmission request and the data block selected by the data coding section 11 as data blocks transmitted in the same data packet.

The data storage device 12 has a storage capacity specified in accordance with a maximum number of times that a single data block can be retransmitted. For example, to allow a design where up to 3 requests can be made for a retransmission of a single data block, the data storage device 12 needs a storage capacity to hold data blocks for 4 cycles, because it takes 4 cycles to complete the third retransmission.

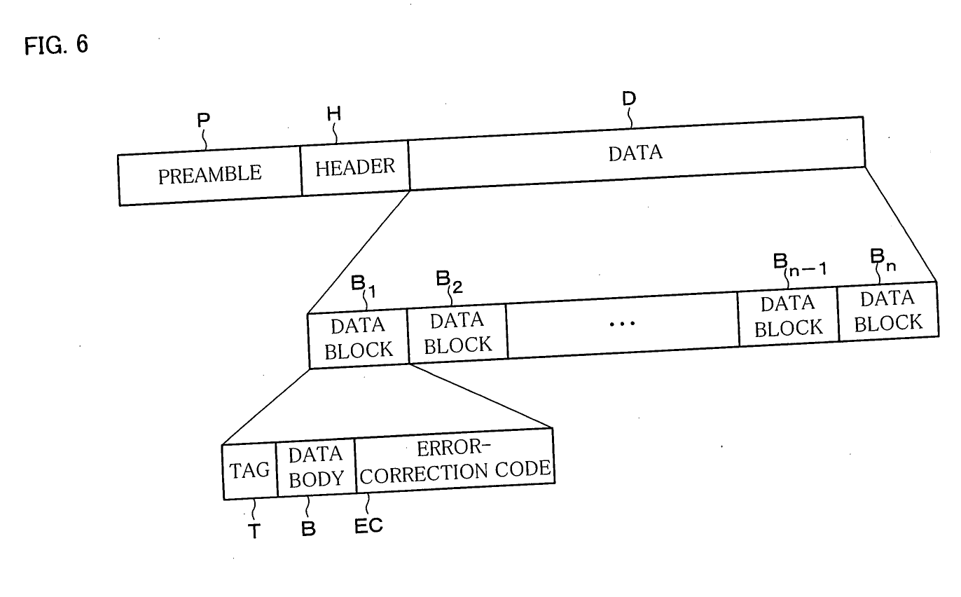

The transmission packet generating section 13 generates a data packet by adding, for example, a header to a data block that has been read from the data storage device 12 for transmission as a single entity in one transmission (one communications cycle). Besides, the transmission packet generating section 13 adds tag information T (see FIG. 6; will be detailed later) to each block on the basis of a result of analysis supplied from the retransmission request packet analyzing section 17 (information on a data block of which a retransmission is being requested).

The error-correction coding section 14 performs an error-correction coding process by adding Hamming, Reed-Solomon, or other error-correction codes to the data block in the data packet supplied from the transmission packet generating section 13.

The data transmitting section 15 transmits the data packet supplied from the error-correction coding section 14 to the leaf node 2. To this end, the data transmitting section 15 includes circuitry for wireless data transmission and for data output interface.

The retransmission request packet receiving section 16 includes circuitry for wireless data reception and for data input interface so as to receive a retransmission request packet transmitted from a retransmission request packet transmitting section 28 (detailed later).

Every time the retransmission request packet transmitting section 28 transmits a retransmission request packet, the retransmission request packet analyzing section 17 analyzes non-received data blocks on the basis of data block numbers indicated in the retransmission request packet. For example, each data block is in advance assigned a bit which represents the sequential position of the target data block of the retransmission request as counted from the header. The retransmission request packet analyzing section 17 compares an input number with the number thus specified, and sets the bit for a matched number to 1. In this manner, the retransmission request packet analyzing section 17 can be arranged from logic circuits. The result of the analysis—the sequential position of the data block a retransmission of which is being requested—is supplied to the data storage device 12 and the transmission packet generating section 13.

Besides, the retransmission request packet analyzing section 17 extracts the block count information (CYCLEn where n is the number of data blocks) in the retransmission request packet as compression information and supplies it the aforementioned data coding section 11 and the data storage device 12. According to the compression information, the data coding section 11 determines the number of data blocks in a data packet to be transmitted in a next communications cycle (hereinafter, simply “cycle”).

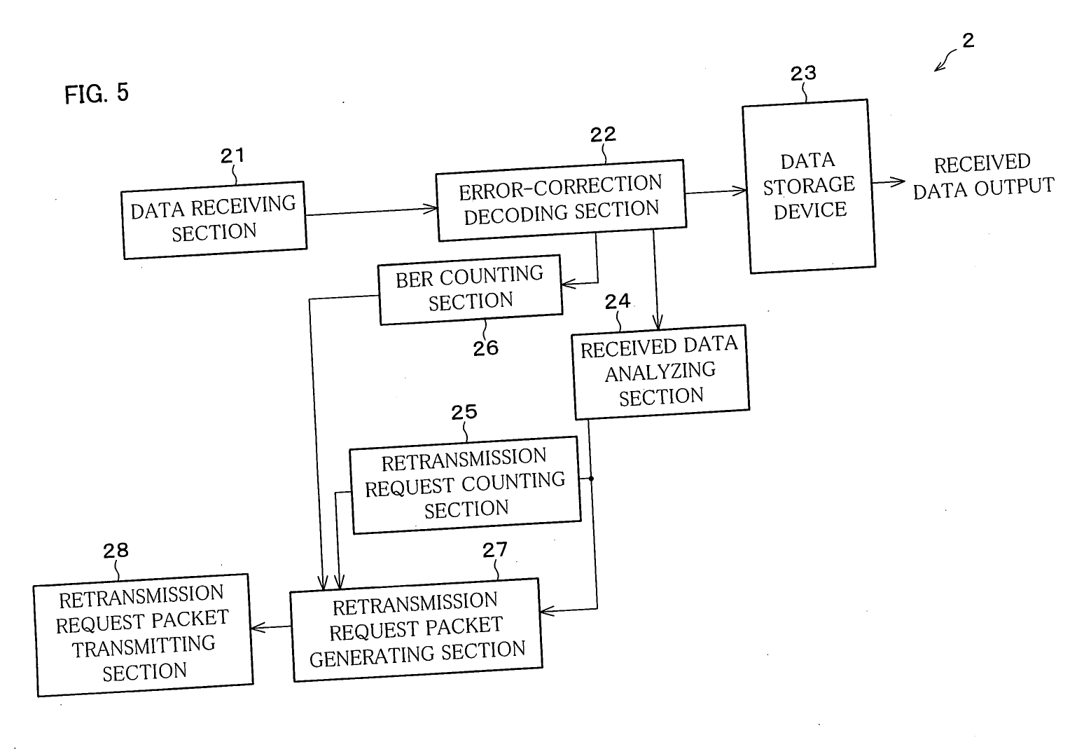

Referring to FIG. 5, the leaf node 2 as a receiver device is provided with a data receiving section 21, an error-correction decoding section 22, a data storage device 23, a received data analyzing section 24, a retransmission request counting section 25, a BER (Bit Error Rate) counting section 26, a retransmission request packet generating section 27, and a retransmission request packet transmitting section 28.

The data receiving section 21 includes circuitry for wireless data reception and for data input interface. The error-correction decoding section 22 as error correction means restores data by performing error-correction decoding on the coded error-correcting data block in the data packet received by the data receiving section 21 using error-correction codes by a predetermined method.

The data storage device 23 includes memory and associated circuitry (e.g., memory control circuit) to temporarily hold received data for later output. The data storage device 23 restores a data packet by arranging the data blocks obtained by decoding in the error-correction decoding section 22 in their sequence and outputs the packet at a predetermined time. As to a data block that the error-correction decoding section 22 has failed to receive due to, for example, unsuccessful decoding, the data storage device 23 waits for a retransmission from the root node 1 and a subsequent successful reception before combining the data block with other, separately stored data blocks to restore the data packet as will be detailed later.

The received data analyzing section 24 analyzes and determines (identifies) correctly received (error-correctable) data blocks a block at a time based on the result from the error-correction decoding section 22. Specifically, the received data analyzing section 24 determines which data blocks have been correctly corrected (received) on the basis of the content of the data whose errors were correctly corrected in the error-correction decoding section 22 (tag information T (see FIG. 6), will be detailed later). The result of the determination is given by way of data block numbers.

Besides, the received data analyzing section 24 as uncorrectable block identifying means recognizes (identifies) non-received (error-uncorrectable) data block on the basis of the data blocks which are determined to have been correctly received. To this end, the received data analyzing section 24 has circuitry which searches the numbers assigned to the data blocks for those missing, that is, those which have not successfully received. As a result of the search, those data blocks which are to be retransmitted are recognized. Further, the received data analyzing section 24 has a register to hold the recognized data blocks.

The retransmission request counting section 25 counts the total number of data blocks, in the received data packet, for which a retransmission request is to be made (the number of times a retransmission request is to be made) by incrementing by 1 every time a piece of the information on the data blocks to be retransmitted which has been obtained by the received data analyzing section 24 is received. To this end, the retransmission request counting section 25 has a counter.

The BER counting section 26 counts the total number of errors in the received data packet on the basis of the result of processing by the error-correction decoding section 22. To this end, the BER counting section 26 has a counter. Besides, the BER counting section 26 calculates the number of errors (the number of bytes) per unit time as the number of error occurrences from the counted total number.

The retransmission request packet generating section 27 generates a retransmission request packet inclusive of the information on the data blocks which have not been successfully received from the received data analyzing section 24, to request a retransmission of the data blocks. To this end, the retransmission request packet generating section 27 generates a reproduction request packet by adding a header, etc. to the data blocks a retransmission of which is to be requested.

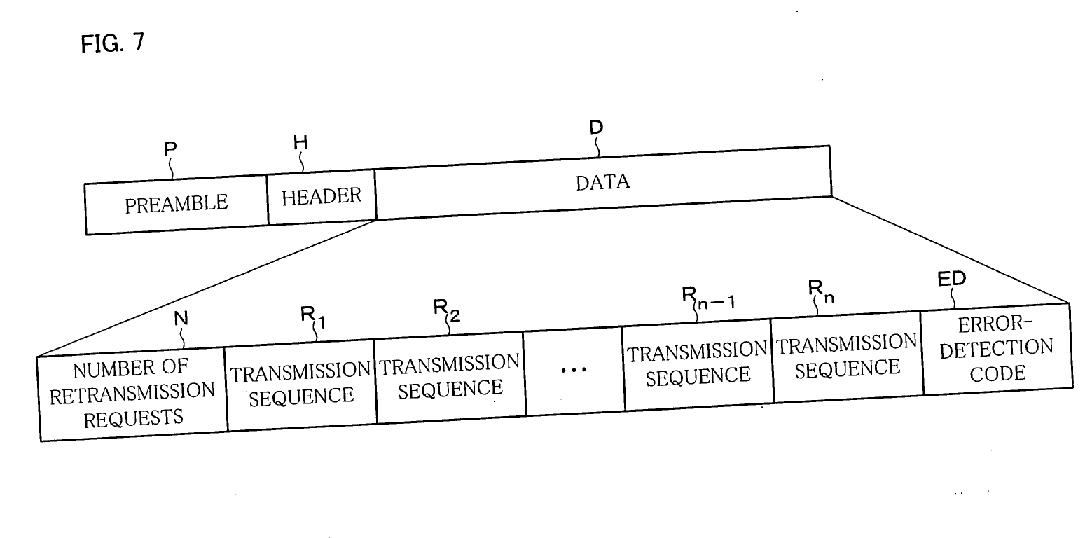

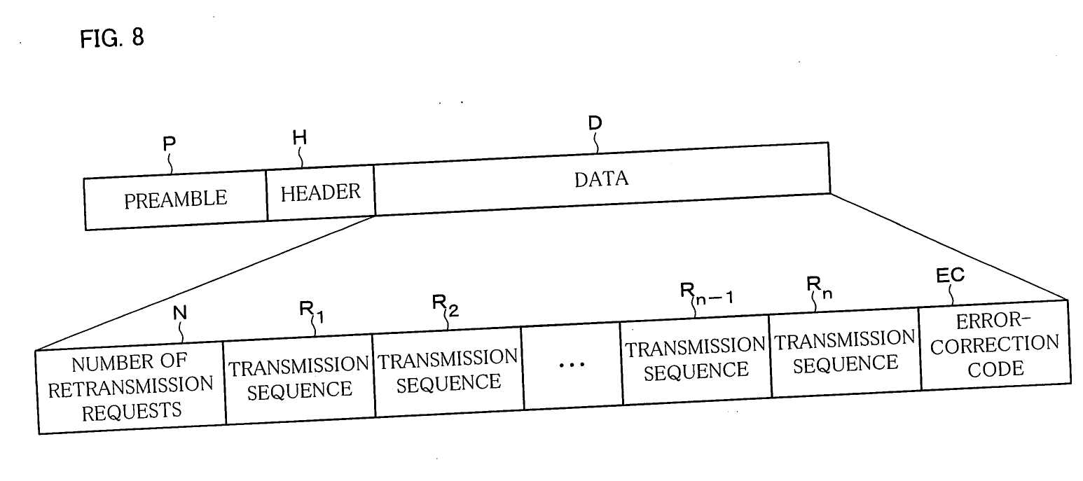

Besides, if the number of times a retransmission request is to be made provided by the retransmission request counting section 25 or the number of error occurrences provided by the BER counting section 26 exceeds a specified value, the retransmission request packet generating section 27 as request generating means determines that communications conditions have deteriorated and subsequently generates the aforementioned block count information as a request to reduce the size of the data packet to be transmitted (block count alteration request). The block count information is included in information, N, on the number of retransmission requests in the retransmission request packet (detailed later, see FIG. 7 and FIG. 8). The retransmission request packet generating section 27 determines in advance whether to generate the block count information on the basis of the number of times a retransmission request is to be made or the number of error occurrences.

The retransmission request packet transmitting section 28 includes circuitry for wireless data transmission and for data output interface to transmit the retransmission request packet to the root node 1.

In the leaf node 2, the received data analyzing section 24 analyzes the correctly corrected data blocks and recognizes those data blocks for which errors have not been corrected on the basis of the analysis. In contrast, feeding the data blocks for which errors have not been corrected to the received data analyzing section 24 in order to directly determine those data blocks may cause the received data analyzing section 24 to produce a wrong analysis, because the information that the data itself has not been correctly corrected may possibly be wrong. The data blocks which should be retransmitted are thus correctly determined from the analysis based on the correctly corrected data blocks.

Here, the data packet transmitted from the root node 1 and the retransmission request packet transmitted from the leaf node 2 will described in terms of their format.

As shown in FIG. 6, the transmitted data packet is composed of a physical layer preamble P, a physical layer header H, and data D. The data. D is divided into n data blocks B₁-Bₙ (error correction block). Each data block B₁-Bₙ is made up of a data body B to which are added tag information T and an error-correction code EC.

The tag information T includes retransmission sequence specifying information for the data blocks B₁-Bₙ and an identifier indicating the data blocks to be retransmitted. The retransmission sequence specifying information may be, for example, either a sequence series for each piece of block information or a combination of a packet number and a block number. In this example, each data block B₁-Bₙ includes tag information T. This is however not essential: for example, the tag information T for all the data blocks B₁-Bₙ may collectively be added to the head of the data D.

Each data block is 188 plus something byte long, inclusive of a margin for retransmission (detailed later) and error-correction code information when, for example, transmitted using MPEG. Therefore, the data D has a length equal to 188 plus something multiplied by an integer.

Referring to FIG. 7, the retransmission request packet is composed of a physical layer preamble P, a physical layer header H, and data D, similarly to the transmitted data packet. A difference is however found in the arrangement of the data D. The data D is made of up information, N, on the number of retransmission requests, n pieces of transmission sequence specifying information R₁-Rₙ, and an error-detection code ED. The root node 1 determines a retransmission sequence for the data blocks B₁-Bₙ on the basis of the transmission sequence specifying information R₁-Rₙ.

In this format for the retransmission request packet, the data D includes the error-detection code ED to enable the root node 1 to detect errors. Alternatively, an error-correction code EC may replace the error-detection code as shown in FIG. 8.

In the leaf node 2 in the communications system thus arranged, a data packet from the root node 1 is received by the data receiving section 21 and undergoes error correction in the error-correction decoding section 22 a data block at a time, before being stored in the data storage device 23. Information on data blocks for which error correction has been impossible and a request should be made for a retransmission is obtainable from the block-by-block analysis conducted by the received data analyzing section 24 on the basis of a result of the error correction by the error-correction decoding section 22. Besides, the number of times a retransmission request is to be made is obtainable from the count by the retransmission request counting section 25 on the basis of the information on the data blocks a retransmission of which is to be requested. Meanwhile, the number of error occurrences is obtainable on the basis of a result of the error correction by the error-correction decoding section 22.

The retransmission request packet generating section 27 generates block count information on the basis of the number of times a retransmission request is to be made or the number of error occurrences so as to determine the number of data blocks in the next transmitted data packet and adds the information to the retransmission request packet. The retransmission request packet is transmitted from the retransmission request packet transmitting section 28 to the root node 1.

The root node 1 receives the retransmission request packet and transmits a transmitted data packet including retransmitted data blocks in accordance with the retransmission request (detailed later). If the leaf node 2 correctly receives the retransmitted data blocks, the node 2 stores the blocks in the data storage device 23. The retransmitted data blocks, together with already stored data blocks, are arranged in a sequence and output as receive data.

Meanwhile, in the root node 1, the retransmission request packet receiving section 16 receives the retransmission request packet from the leaf node 2, and the retransmission request packet analyzing section 17 analyzes data blocks a retransmission of which is needed and extracts block count information necessary for data compression. The information and the block count information in the retransmission request obtained by the retransmission request packet analyzing section 17 is sent to the data coding section 11 and the data storage device 12.

The data coding section 11 changes the data compression ratio on the basis of the block count information and outputs compressed data to the data storage device 12 so as to ensure new input data to be transmitted in the next and subsequent cycles. The transmission packet generating section 13 reads the retransmission block and new blocks from the data storage device 12 on the basis of the block count information to ensure retransmitted data blocks in a data packet to be transmitted in a next cycle.

The data storage device 12 is holding the thus inputted new data block and the data blocks in the data packet transmitted in the last and previous cycles. From the data storage device 12, a combination of new and old data blocks are read on the basis of the retransmission request information obtained by the retransmission request packet analyzing section 17. The readout data blocks are limited to the aforementioned number of blocks. Next, a data packet is generated by adding a header and the like to the readout data block group. The error-correction coding section 14 then adds an error-correction code to each data block in the data packet. In this manner, a data packet is generated in which errors in each data block are correctable independently from the other blocks. The data packet from the error-correction coding section 14 is transmitted from the data transmitting section 15 to the leaf node 2.

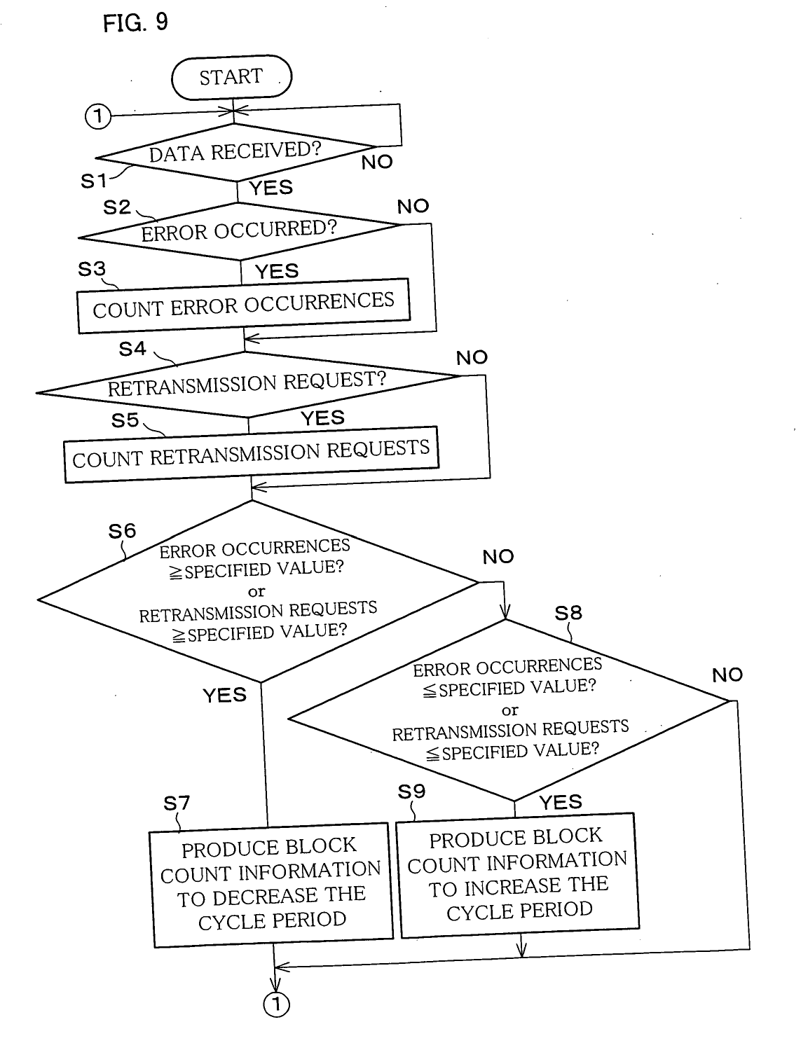

Now, operations of the communications system will be described in reference to the flow chart in FIG. 9.

First, when the root node 1 generates a transmitted data packet in accordance with a transmission sequence and transmits it, the leaf node 2 receives it (S1). In the leaf node 2, the next step differs depending on whether or not a result of the error-correction decoding by the error-correction decoding section 22 shows an error being involved in a received data block (S2). If there has been involved an error, the BER counting section 26 counts the number of error occurrences per unit time (S3), before the process proceeds to S4. An error occurrence is determined depending on whether an error correction has been performed in the error-correction decoding. On the other hand, if there has been involved no error in S2, the process proceeds directly to S4.

In S4, the next step differs depending on whether or not a result of the analysis by the received data analyzing section 24 shows there being any error-uncorrectable data block (S4). Here, if there is an error-uncorrectable data block, the retransmission request counting section 25 counts the aforementioned number of times a retransmission request is to be made (S5), before the process proceeds to S6. On the other hand, if there is no error-uncorrectable data block in S4, the process proceeds directly to S6.

In S6, the next step differs depending on whether the number of error occurrences counted by the retransmission request packet generating section 27 in S3 is more than or equal to a specified value or whether the number of times a retransmission request is to be made counted in S5 is more than or equal to a specified value (S6). If the number of error occurrences or the number of times a retransmission request is to be made is more than or equal to a specified value, block count information is produced which shortens the period of 1 cycle (shortens the data packet in 1 cycle) (S7), and the process returns to S1.

On the other hand, if in S6 the number of error occurrences or the number of times a retransmission request is to be made is less than the specified value, the next step differs depending on whether the number of error occurrences or the number of times a retransmission request is to be made is less than or equal to a specified value (S8). Here, if the number of error occurrences or the number of times a retransmission request is to be made is less than or equal to the specified value, block count information is produced which lengthens the period of 1 cycle (lengthens the data packet in 1 cycle) (S9), and the process returns to S1. On the other hand, if in S8 the number of error occurrences or the number of times a retransmission request is to be made is more than the specified value, the process returns directly to S1.

Note that basically the specified value to which the number of error occurrences or the number of times a retransmission request is to be made is compared differs in S6 and in S8: the specified value in S6 is larger than the specified value in S8.

If the number of error occurrences is used in S6 and S8, S4 and S5 are omittable. If the number of times a retransmission request is to be made is used in S6 and S8, S2 and S3 are omittable.

As detailed so far, in the communications system of the present embodiment, when the number of error occurrences in a data block or the number of times a reproduction request is to be made in a data block exceeds a specified value because of, for example, deteriorating reception conditions, the number of retransmittable data blocks can be increased by raising the data compression ratio and shortening the cycle period. This prevents occurrence of block noise caused by missing data due to an unretransmittable data block although the quality of reproduced data may decrease somewhat (for example, a video image appear less smooth).

Besides, when the number of error occurrences in a data block or the number of times a reproduction request is to be made in a data block is less than a specified value due to, for example, improved reception conditions, there is almost no need for data block retransmission. In contrast, in the present communications system, lengthening the cycle period enables reproduction of original information, while maintaining the quality of the transmitted data.

A specific example will described in example 1.

In the process illustrated in the flow chart, the number of times a data block is retransmitted is increased by shortening the data packet length per 1 cycle (1 cycle period). Alternatively, as will be explained in example 2 (detailed later), the occurrence of block noise can be prevented similarly without changing the duration of the 1 cycle period.

### EXAMPLE 1

In the present example, as shown in FIG. 1, the data packet transmitted from the root node 1 normally contains a header and 6 new data block following the header. For example, the data packet P(1) transmitted from the root node 1 contains a header H(1) and data blocks B(101) to B(106) provided based on an error correction unit.

The leaf node 2 receives the data packet P(1). If an error correction is done correctly, the leaf node 2 transmits a response packet A(1) containing a positive respond ACK to the root node 1. If the root node 1 receives the positive respond ACK from the leaf node 2 and confirms that the leaf node 2 has successfully received the data packet P(1), the root node 1 transmits a data packet P(2) in a next cycle.

In the cycle, since the leaf node 2 has failed to receive a data block B(206) in the data blocks B(201) to B(206) in the data packet P(2), the leaf node 2 transmits a retransmission request packet A(2) containing retransmission request information R(206) which is a request for its retransmission. As the root node 1 receives the retransmission request packet A(2), the root node 1 transmits the data packet P(3) containing a data block B(206) at the front and the succeeding data blocks B(301) to B(306) in a next cycle.

By contrast, the leaf node 2 has successfully received the data block B(206), but failed to receive the data blocks B(302), B(303), B(305); the leaf node 2 therefore transmits a retransmission request packet A(3) containing retransmission request information R(302, 303, 305) and block count information CYCLE5 which is a request for its retransmission.

As the root node 1 receives the retransmission request packet A(3), the root node 1 transmits new data blocks compressed into four blocks in a succeeding cycle. The CYCLE5 refers to the five blocks including those four blocks and the header (one block). For example, the data packet P(4) contains the data blocks B(302), B(303), B(305) for which a retransmission request was made by the leaf node 2 in the third cycle, as well as the two data blocks B(401), B(402) out of the four data blocks B(401) to B(404) which should be normally transmitted in this cycle.

Thus, the cycle periods are shortened by the time t over the fourth through the seventh cycle.

In this manner, the number of retransmissions of the data blocks can be increased by reducing the number of newly transmitted data blocks to increase the compression ratio for the data blocks and reducing the length of the data packet per cycle through processing of the data coding section 11 to reduce the cycle period.

This increases the compression ratio and therefore lowers quality of reproduced data (e.g. image quality), but enables a retransmission of as many data blocks as possible in a time required for a real time transmission and greatly restrains occurrence of block noise. Data transmission is therefore secured.

If the leaf node 2 successfully receives continuous data blocks (a continuous state where no retransmission request) and successfully receives all new data blocks in the same group per cycle when, for example, reception conditions improve, the leaf node 2 transmits block count information to restore the compression ratio for the data blocks to the previous value. For example, if the leaf node 2 successfully receives a data packet P(7) containing all the four data blocks B(701) to B(704) in the same group, the leaf node 2 transmits to the root node 1 block count information CYCLE7 according to which compression into six data blocks will be made. Thus, the root node 1 transmits a data packet P(8) containing the six data blocks B(801) to B(806) in a next cycle.

In this manner, under good communications conditions, increasing the duration of one cycle enables transmission of more new data blocks, and therefore ensures that data is transmitted without decreasing reproduced data quality.

As in the foregoing, in the present example, the number of retransmissions of a data block is changed by changing the cycle period in accordance with the block count information. This enables an optimal transmission rate to be selected in accordance with reception conditions.

### EXAMPLE 2

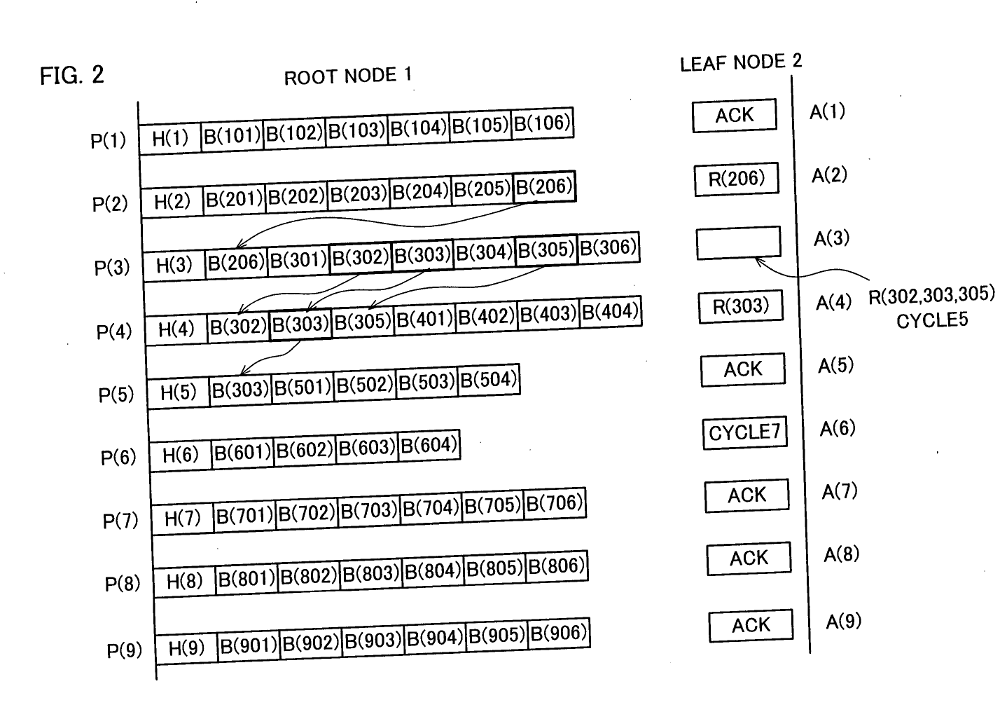

As shown in FIG. 2, in the present example, the data packet transmitted from the root node 1 also usually contains a header and six succeeding new data blocks similarly to example 1. However, in the present example, even if the root node 1 transmits a retransmission request packet A(3) containing the retransmission request information R(302, 303, 305) and the block count information CYCLE5 in the third cycle from the leaf node 2, the root node 1 transmits the data packet P(4) containing the data blocks B(302), B(303), B(305) for which a retransmission request should be made, as well as the four data blocks B(401) to B(404) without reducing the cycle period in a next cycle, by means of the data coding section 11.

In the sixth cycle, since there is no data block to be retransmitted, the data packet P(6) is composed of the four data blocks B(601) to B(604) to be transmitted in this cycle.

In this manner, increasing the compression ratio for the data block without changing the cycle period enables a new transmission of the data blocks B(401) to B(404) and secures an additional bandwidth for the data blocks B(302), B(303), B(305) to be retransmitted. This increases the number of retransmissions of a data block and enables a retransmission of as many data blocks as possible in a time required for a real time transmission and greatly restrains occurrence of block noise, similarly to example 1. Data transmission is therefore secured.

Besides, in the present example, the new transmit data blocks are transmitted in a single cycle, without crossing over into the next cycle: if reception conditions improve, the data coding section 11 can quickly restore the compression ratio for the data blocks to the previous value as below.

Suppose that the root node 1 replies to a retransmission request for a data block B(303) from the leaf node 2 in the fourth cycle, by transmitting the data packet P(5) containing the data block B(303) and the data blocks B(501) to B(504) in the same group in a next cycle. If the leaf node 2 has successfully received the data packet, the root node 1 transmits the four data blocks B(601) to B(604) in the same group by means of the data packet P(6) in a next cycle. Therefore, the leaf node 2, having successfully received it, has now successfully received the data blocks of the same group twice, and transmits block count information CYCLE7 to the root node 1 so that the number of blocks is six. The root node 1 then decreases the compression ratio to six blocks and transmits the data packet P(7).

In this manner, in the present example, the transmission rate can be restored to the ordinary value one cycle earlier than in example 1.

[Embodiment 2]

The present embodiment will describe an arrangement where the function of the communications system illustrated in embodiment 1 is partly changed. The present embodiment will refer to the same figures as embodiment 1.

FIG. 3 is a block diagram showing an arrangement of a communications system according to the present embodiment (the present system). As shown in the figure, the present system includes a root node 1 as a transmitter device and a leaf node 2 as a receiver device.

The root node 1 and the leaf node 2 are linked by wireless communications (communications by means of, for example, a radio wave or infrared wave).

In other words, in the present system, the root node 1 divides externally provided new data into multiple blocks (data blocks) to generate a data packet containing a predetermined number of data blocks and transmit them to the leaf nodes 2.

“New data” means video/audio data provided in real time from, for example, a video camera or television set. Each data block (for example, B(101) to B(106) in FIG. 1) contains coded error-correcting data.

Meanwhile, the leaf node 2 error-correction decodes the data blocks in the received data packet and transmits, to the root node 1, a retransmission request of data blocks for which errors were not completely corrected.

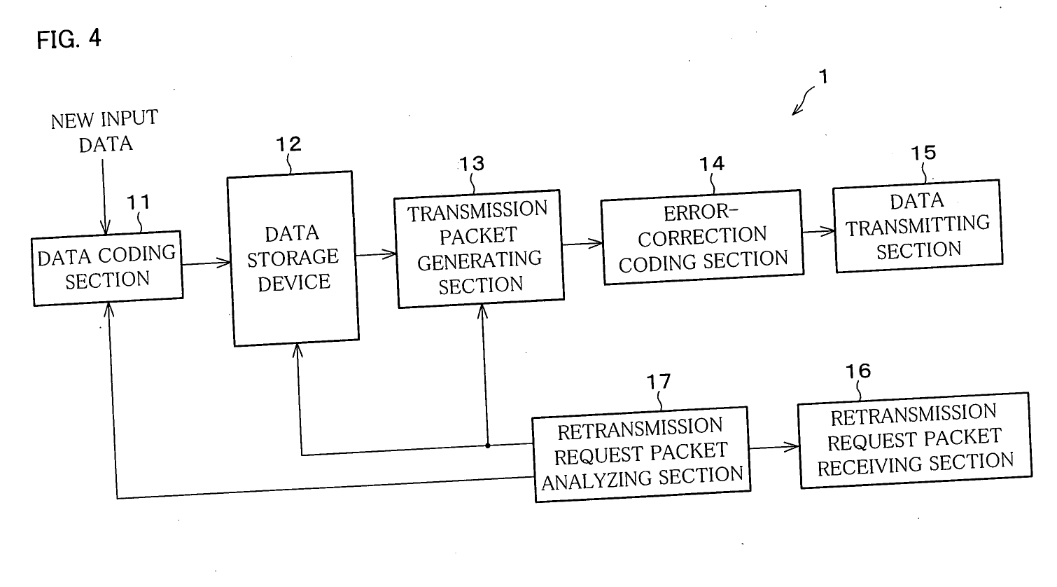

First, the arrangement of the root node 1 will described. FIG. 4 is a block diagram showing an arrangement of the root node 1. As shown in the figure, the root node (transmitter device) 1 includes a data coding section 11, a data storage device 12, a transmission packet generating section 13, an error-correction coding section 14, a data transmitting section 15, a retransmission request packet receiving section 16, and a retransmission request packet analyzing section 17.

The data coding section 11 divides, for output, new data (new input data) from a video camera or the like into predetermined data blocks, so that the error-correction coding section 14 (detailed later) can code the data blocks one by one (detailed later).

Besides, the data coding section 11 has a function of performing data compression on each data block where necessary (the compression process will be detailed later).

The data storage device (data block storage means) 12 has a memory and related circuits (e.g., a memory control circuit) to temporarily store data (data blocks) supplied from the data coding section 11 in the memory.

The transmission packet generating section 13 reads a data block group (a data block which forms a single entity to be transmitted by a single transmission (communications cycle); a transmission data block group) from the data storage device 12 for transmission as a single data packet and adds, for example, a header to the data block group, to generate a data packet (transmitted data packet).

The transmission packet generating section 13 generates a transmission data block group from a data block related to new data and a data block related to a retransmission. The process will be detailed later.

The error-correction coding section 14 performs an error-correction coding process by adding Hamming, Reed-Solomon, or other error-correction codes to each data block in the data packet generated by the transmission packet generating section 13.

FIG. 6 is an explanatory drawing showing an arrangement of a data packet generated by the transmission packet generating section 13 and processed by the error-correction coding section 14. As shown in the figure, the data packet is made up of a physical layer preamble P, a physical layer header H, and data D.

The data D is made up of n divisional data blocks B₁-Bₙ (error correction blocks) each of which is made by appendixing tag information T and an error-correction code EC to data body B.

The tag information T contains transmission block information which is an identifier identifying the data blocks B₁-Bₙ and indicating the transmission sequence for the data blocks. In the present embodiment, the transmission block information is made up of block numbers (1-n) assigned to the respective data blocks. The transmission sequence is by block number (either ascending or descending order).

The tag information T of a data block related to retransmission includes information indicating that the data block is related to retransmission (retransmission information).

The data block is 188 plus something byte long, inclusive of the tag information T and the error-correction code EC (correction coding information) when, for example, transmitting using MPEG. Therefore, the data D has a length equal to 188 plus something multiplied by an integer.

The data transmitting section 15 is for transmitting the data packet processed by the error-correction coding section 14 to the leaf node 2. To this end, the data transmitting section 15 includes circuitry for wireless data transmission and for data output interface.

The retransmission request packet receiving section 16 and the retransmission request packet analyzing section 17 are members processing a retransmission request packet transmitted from the leaf node 2, and will be detailed later.

Next, an arrangement of the leaf node 2 will be described. FIG. 5 is a block diagram showing an arrangement for the leaf node 2. As shown in the figure, the leaf node (receiver device) 2 includes a data receiving section 21, an error-correction decoding section 22, a data storage device 23, a received data analyzing section 24, a retransmission request counting section 25, a BER (Bit Error Rate) counting section 26, a retransmission request packet generating section 27, and a retransmission request packet transmitting section 28.

The data receiving section 21 includes circuitry for wireless data reception and for data input interface and receives data packets transmitted from the root node 1.

The error-correction decoding section (error correction means) 22 decodes the data blocks in the data packet received by the data receiving section 21. In the decoding, error-correction decoding is performed on the data blocks on the basis of a predetermined scheme using error-correction codes.

The error-correction decoding section 22 adds to the decode data blocks information (decoding result information) related to whether or not the data blocks have been decoded correctly.

The data storage device 23 includes a memory and related circuits (e.g., a memory control circuit) to temporarily store the data blocks decoded by the error-correction decoding section 22.

The data storage device 23 has a function of restoring a data packet by arranging the decoded data blocks in their sequence and outputs the packet at a predetermined timing.

If the error-correction decoding section 22 has failed to decode a data block (to correctly error correct), the data storage device 23 further waits for the completion of a retransmission/decoding of that data block before restoring (or outputting) the data packet. Specifically, the data storage device 23 is adapted to wait for successful decoding of the data block retransmitted from the root node 1, and once the decoding is successful, combine that data block with other, stored data blocks to restore the data packet. In this manner, the data storage device 23 restores a data packet after all the data blocks in that data packet is correctly decoded.

The received data analyzing section 24 recognizes (identifies) data blocks that are decoded (correctly error corrected) on the basis of the decoding result information added by the error-correction decoding section 22.

That is, the received data analyzing section 24 identifies data blocks decoded by the error-correction decoding section 22 according to decoding result information, and stores the block numbers (the transmission block information in the tag information T, see FIG. 6) of the data blocks.

The received data analyzing section 24 as uncorrectable block identifying means recognizes (identifies) the block numbers of undecoded data block on the basis of the block numbers of data blocks determined to have been decoded.

To this end, the received data analyzing section 24 includes a circuit which searches for the block numbers of undecoded data blocks by comparing the block numbers of all the data blocks to those of the decoded data blocks. The received data analyzing section 24 recognizes those data blocks for which a retransmission request should be sent (retransmission-required data blocks; undecoded data blocks) through the search using the circuit.

To implement the process, the received data analyzing section 24 includes a register storing the recognized block numbers.

The received data analyzing section 24 is adapted to notifies the retransmission request counting section 25 every time it identifies a retransmission-required data block (or its block number).

The retransmission request counting section 25 has a counter incremented every time it is notified that a retransmission-required data block is identified, and is adapted to obtain the total number of retransmission-required data blocks (number of retransmission requests) in the received data packet by means of the counter.

The BER counting section 26 counts the total number of errors (total error count) in the received data packet based on the result of the process by the error-correction decoding section 22. To this end, the BER counting section 26 has a counter. Also, the BER counting section 26 calculates the number of errors (number of bytes) per unit time from the total error count and recognizes a result of the calculation as the number of error occurrences.

The retransmission request packet generating section 27 generates a retransmission request packet containing transmission block information (block numbers) for the retransmission-required data blocks obtained through the received data analyzing section 24 and making a request for a retransmission of the retransmission-required data blocks.

FIG. 7 is an explanatory drawing showing a retransmission request packet generated by the retransmission request packet generating section 27. As shown in the figure, the retransmission request packet is made up of a physical layer preamble P, a physical layer header H, and data D similarly to the data packet in FIG. 6, except that the data D has a different structure.

The data D is made up of information, N, on the number of retransmission requests, retransmission block information sets R₁-Rₙ, and an error-detection code ED. In the present embodiment, the retransmission block information sets R₁-Rₙ are made up of the block numbers of the retransmission-required data blocks. The root node 1 identifies retransmission-required data blocks and determines their retransmission sequence on the basis of the retransmission block information sets R₁-Rₙ.

In the format of this retransmission request packet, the data D includes the error-detection code ED so that the root node 1 can detect an error. Alternatively, as shown in FIG. 8, the error-detection code may be replaced with an error-correction code EC.

The retransmission request packet generating section 27 as request generating means compares the number of retransmission requests as counted by the retransmission request counting section 25 to two kinds of predetermined, predefined values, that is, a first predefined retransmission value and a second predefined retransmission value (the first predefined retransmission value>the second predefined retransmission value). Further, the retransmission request packet generating section 27 compares the number of error occurrences as counted by the BER counting section 26 to two kinds of predetermined, predefined value, that is, a first predefined error value and a second predefined error value (the first predefined error value>the second predefined error value).

If the number of retransmission requests is more than or equal to the first predefined retransmission value or the number of error occurrences is more than or equal to the first predefined error value, the retransmission request packet generating section 27 determines that communications conditions have deteriorated and generates block count information (a block count alteration request) to send a request to the root node 1 that a data packet transmitted next should be reduced in size.

In contrast, if the number of retransmission requests is less than the second predefined retransmission value or the number of error occurrences is less than the second predefined error value, the retransmission request packet generating section 27 determines that communications conditions are good and generates block count information (a block count alteration request) to send a request to the root node 1 that a data packet transmitted next should be increased in size.

The block count information is information by which the number of data blocks transmitted in one data packet is determined. Besides, the retransmission request packet generating section 27 includes the block count information in the information, N, on the number of retransmission requests (see FIG. 7, 8) in the retransmission request packet.

The retransmission request packet transmitting section 28 is a part including circuitry for wireless data transmission and for data output interface and transmits the retransmission request packet to the root node 1.

Here, we will describe the retransmission request packet receiving section 16 and the retransmission request packet analyzing section 17 at the root node 1 illustrated in FIG. 4.

The retransmission request packet receiving section 16 receives a retransmission request packet transmitted from the retransmission request packet transmitting section 28 of the leaf node 2, and includes circuitry for wireless data reception and for data input interface.

The retransmission request packet analyzing section 17 analyzes a received retransmission request packet and identifies retransmission-required data blocks on the basis of a retransmission block information set (that is, block number) in the retransmission request packet.

For example, the retransmission request packet analyzing section 17 assigns to each data block a bit representing which data block in the transmitted data packet will be retransmitted, and renders “11” the bit for the data blocks having the block numbers included in the retransmission request packet. Thus, the retransmission request packet analyzing section 17 can be constructed from logic circuits. The result of analysis related to for which data blocks a retransmission request was made (the block numbers of the retransmission-required data blocks) is supplied to the data storage device 12 and the transmission packet generating section 13.

The retransmission request packet analyzing section 17 extracts as compression information the block count information (CYCLEn where n=number of data blocks) in the retransmission request packet, and notifies the data coding section 11 and the transmission packet generating section 13.

Next, we will describe compression by the data coding section 11 and generation (selection) of a transmission data block group by the transmission packet generating section 13.

The data coding section 11 determines (calculates) the number of data blocks and the suitable data compression ratio for a data packet to be transmitted in a next communications cycle (or simply “cycle”) on the basis of compression information supplied from the retransmission request packet analyzing section 17.

Here, the data compression ratio can be calculated using a table (correspondence table) provided to, for example, the root node 1 in advance which associated the number of data blocks to a data compression ratio. The data coding section 11 compresses new data using the calculated data compression ratio.

Upon reception of the compression information (block count information), the transmission packet generating section 13 changes the communications cycle (corresponds to the number of data blocks per data packet) in accordance with the information.

When the number of data blocks in a data packet is reduced (the communications cycle becomes shorter), a scheduled number of new data blocks (new data blocks; data blocks which have been never transmitted) cannot be transmitted in a single data packet depending upon the number of retransmission-required data blocks.

In this case, the transmission packet generating section 13, selects new data blocks to be included in the data packet on the basis of block count information. The transmission packet generating section 13 then is adapted to read the selected new data blocks from the data storage device 12. The selection has been already specifically explained in example 1 above. Unselected new data blocks are transmitted in the next and subsequent data packets.

The transmission packet generating section 13 reads the retransmission-required data blocks (data in data blocks) from the data storage device 12. That is, the transmission packet generating section 13 is specified to read retransmission-required data blocks from the memory on the basis of the block numbers of the retransmission-required data blocks identified by the retransmission request packet analyzing section 17.

In this manner, the transmission packet generating section 13 has a function of reading the new data blocks selected from the new data block group and the retransmission-required data blocks from the data storage device 12 as a transmission data block group on the basis of the block count information and the block numbers of the retransmission-required data blocks.

The transmission packet generating section 13 adds the tag information T shown in FIG. 6 to the retransmitted data blocks on the basis of the result of the analysis (block numbers of the retransmission-required data blocks) by the retransmission request packet analyzing section 17.

Incidentally, the storage capacity of the data storage device 12 is specified in accordance with a maximum number of possible retransmissions of a single data block. For example, in cases where the present system is designed to allow up to three retransmissions of a request for a single data block, the data storage device 12 preferably has a capacity to store data blocks for 4 cycles. This is because it takes 4 cycles to perform 3 retransmissions.

In the present system thus arranged, at the leaf node 2, as the data receiving section 21 receives a data packet from the root node 1, the data packet is decoded by the error-correction decoding section 22 a data block at a time and stored in the data storage device 23. The block numbers of data blocks (retransmission-required data blocks) for which decoding failed are obtainable from a result of the analysis by the received data analyzing section 24 using the decoding result information of the error-correction decoding section 22.

The number of retransmission requests is obtained by the counting by the retransmission request counting section 25 on the basis of the block numbers of the retransmission-required data blocks. Meanwhile, the number of error occurrences is obtained on the basis of a result of the error correction by the error-correction decoding section 22.

The retransmission request packet generating section 27 generates block count information by which the number of data blocks in a next data packet is determined, on the basis of the number of retransmission requests or the number of error occurrences, and adds to the retransmission request packet. The retransmission request packet is transmitted from the retransmission request packet transmitting section 28 to the root node 1.

As the root node 1 receives the retransmission request packet, the root node 1 transmits to the leaf node 2 a data packet including retransmission-required data blocks in accordance with the retransmission request packet. At the leaf node 2, the retransmission-required data blocks are decoded and stored in the data storage device 23. The decoded retransmission-required data blocks are arranged sequentially together with the already stored data blocks and output as received data.

Meanwhile, at the root node 1, the retransmission request packet transmitted from the leaf node 2 is received by the retransmission request packet receiving section 16. The retransmission request packet analyzing section 17 extracts the block numbers of the retransmission-required data blocks and block count information required for data compression. The block count information and the block numbers of the retransmission-required data blocks obtained by the retransmission request packet analyzing section 17 are conveyed to the data coding section 11, the data storage device 12, and the transmission packet generating section 13.

At the data coding section 11, the data compression ratio is changed on the basis of the block count information. Compressed new data blocks are generated from new data to be transmitted in the next and subsequent cycles and stored in the data storage device 12.

In the data storage device 12 are stored the new data blocks input from the data coding section 11 and the data blocks in a data packet transmitted in the last and previous cycles.

The transmission packet generating section 13 selects new data blocks to be transmitted in the next cycle on the basis of the block number of the retransmission-required data blocks and its number obtained by the retransmission request packet analyzing section 17 as well as the block count information. The transmission packet generating section 13 reads the selected new data blocks and the retransmission-required data blocks from the data storage device 12 as transmission data block group on the basis of the block count information. The number of transmission data block groups is limited to values in accordance with the block count information.

Next, the transmission packet generating section 13 generates a data packet by adding a header and the like to the transmission data block group readout. The error-correction coding section 14 then adds an error-correction code to the data packet for each data block. Each data block constituting the error correctable data packet is thus generated. The data packet processed by the error-correction coding section 14 is transmitted to the leaf node 2 by the data transmitting section 15.

Next, we will describe the operation of the present system in reference to the flow chart in FIG. 9. First, the root node 1 generates and transmits a data packet in accordance with a transmission sequence, which is received by the leaf node 2 (S1). At the leaf node 2, the next step differs depending on whether the result of the error-correction decoding by the error-correction decoding section 22 indicates an occurrence of an error(s) in a received data block (S2).

If errors have occurred, the BER counting section 26 counts the number of error occurrences per unit time (S3), and the operation proceeds to S4. The occurrence of an error is determined according to whether or not an error correction was done in error-correction decoding. If no error occurred in S2, the operation directly proceeds to S4.

In S4, the next step differs depending on whether or not the result of the analysis by the received data analyzing section 24 indicates presence/absence of an unrestored data block (non-error corrected) (S4). If there are any unrestored data blocks, the retransmission request counting section 25 counts the aforementioned number of retransmission requests (S5), and the operation proceeds to S6. If there are no unrestored data blocks in S4, the operation directly proceeds to S6.

In S6, the next step differs depending on whether the number of error occurrences counted in S3 is more than or equal to a first predetermined error value or whether the number of retransmission requests counted in S5 is more than or equal to the first predetermined retransmission value (S6). If the number of error occurrences or is more than or equal to the first predetermined error value or the number of retransmission requests is more than or equal to the first predetermined retransmission value, the retransmission request packet generating section 27 produces block count information which reduces the cycle of 1 cycle (shortening the data packet per cycle) (S7), and the operation returns to S1.

Meanwhile, if in S6, the number of error occurrences is less than the first predetermined error value, or the number of retransmission requests is less than the first predetermined retransmission value, the next step differs depending on whether the number of error occurrences is less than or equal to a second predetermined error value or whether the number of retransmission requests is less than or equal to the second predetermined retransmission value (S8).

Here, if the number of error occurrences is less than or equal to the second predetermined error value or the number of retransmission requests is less than or equal to the second predetermined retransmission value, the retransmission request packet generating section 27 produces block count information which increases the cycle of 1 cycle (lengthening the data packet per cycle) (S9), and the operation returns to S1.

Besides, if in S8 the number of error occurrences or the number of retransmission requests is more than the specified value, the operation returns directly to S1.

Note that basically the specified value to which the number of error occurrences or the number of retransmission requests is compared differs in S6 and in S8: the first predetermined error value is set larger than the second predetermined error value, and the first predetermined retransmission value is set larger the second predetermined retransmission value.

Note that the retransmission request packet generating section 27 may generate block count information using either one of the number of retransmission requests or the number of error occurrences. If only the number of error occurrences is used, S4 and S5 are omittable. If only the number of retransmission requests is used, S2 and S3 are omittable. It is preferably specified in advance whether the retransmission request packet generating section 27 uses either the number of retransmission requests or the number of error occurrences.

In the present embodiment, the root node 1 is adapted to retransmit data blocks which could not be restored by the error-correction decoding section 22 (not error correctable). However, the present embodiment is not limited to this: the root node 1 may retransmit data blocks which could not be correctly received by the leaf node 2.

In the present embodiment, the transmission block information in each piece of block data in the data packet transmitted from the root node 1 and the retransmission block information set in the retransmission request packet transmitted from the leaf node 2 are defined as the block numbers of data blocks.

However, the present embodiment is not limited to this: any transmission block information and any retransmission block information set may be employed as long as they can identify the content and the transmission sequence of the data blocks related to transmission or retransmission. For example, a combination of a packet number and a block number may be used as the transmission block information and the retransmission block information set.

In the present embodiment, the new data blocks to be included in the data packet is specified to be selected by the transmission packet generating section 13. However, the present embodiment is not limited to this: the selection may be done by the data coding section 11.

In the present embodiment, the data blocks to be included in the data packet is specified to be read by the transmission packet generating section 13 from the data storage device 12. However, the reading may be done by a control circuit of the data storage device 12. In this case, the control circuit of the data storage device 12 comes to have a function of causing to output the transmission data block group from the memory.

The aforementioned document 1, “A Two-Step Adaptive Error Recovery Scheme for Video Transmission over Wireless Networks, Daji Qiao and Kang G. Shin, IEEE INFOCOM 2000,” describes that when correct is impossible in an error correction process at a receiving station, transmitting a retransmission request from the receiving station to the transmitting station causes the transmitting station to respond to it by retransmitting data in packets. The scheme renders the packet extremely long (800 to 900 bytes) and requires a broad bandwidth for a single retransmission. Specially, when communications conditions are poor, repeated retransmissions are required; however, the longer the packet length, the less the retransmissions.

Because of this, data transmitted in real time, such as video and audio, cannot be completely transmitted within such a designated time that the data can be played back continuously. As a result, the video/audio playback at the receiving station may be disturbed, cut off, or causes other inconveniences. Block noise may also superimposed on transmitted data, markedly reducing reproduction quality of a video or the like.

The AQR scheme shown in document 1 adds a block error-correction code (RS code) at the transmitting station end and performs error correction based on that information at the receiving station end. The receiving station end transmits a positive ACK or a negative ACK to the transmitting station according to a result of error correction. The transmitting station retransmits the whole packet when it receives a negative ACK or no ACK at all within a timeout interval.

Besides, the objective of the present invention may be put this way: transmit data with an increased image compression ratio, thereby increasing the number of retransmissions, when communications conditions deteriorate when MPEG2 or otherwise compressed data is being transmitted as data.

As in the foregoing, the communications method according to the present invention is a communications method where a data packet transmitted from a transmitting station is received at a receiving station using a data packet, in which data is divided into one or more blocks, containing data blocks each of which has an error-correction code, and is characterized in that:

the receiving station transmits a retransmission request for an error-uncorrectable data block and transmits a block count alteration request which changes a number of data blocks to be newly transmitted in accordance with good/poor communications conditions on the basis of a result of error correction; and

the transmitting station transmits data blocks to be retransmitted in accordance with a retransmission request and new data blocks changed in accordance with a block count alteration request in the same data packet.

The transmitter device according to the present invention, to solve the problems, is a transmitter device for transmitting to a receiver device a data packet, in which data is divided into one or more blocks, containing data blocks each of which has an error-correction code, and is characterized in that:

when having received a retransmission request for error-uncorrectable data blocks and a block count alteration request which changes a number of data blocks to be newly transmitted in accordance with good/poor communications conditions, transmitted from the receiver device, the transmitter device transmits data blocks to be retransmitted in accordance with a retransmission request and new data blocks changed in accordance with a block count alteration request in the same data packet.

According to the arrangement, the transmitting station (transmitter device) transmits a data packet containing one or more data blocks to a receiving station (receiver device); the receiving station therefore performs separate error correction on each data block upon receipt of the data packet.

When there are error-uncorrectable data blocks, the receiving station transmits a retransmission request requesting the transmitting station to retransmit the data blocks. Besides, when communications conditions deteriorate due to obstruction or environment, if the receiving station determines on the basis of a result of error correction that communications conditions have deteriorated, the receiving station transmits a block count alteration request to restrict the number of data blocks to be newly transmitted. Meanwhile, as the transmitting station receives the retransmission request and the block count alteration request, the transmitting station transmits data blocks in accordance with it and data blocks changed (reduced) in accordance with the block count alteration request in the same data packet.

Besides, when communications conditions have improved, if the receiving station determines on the basis of a result of error correction that communications conditions are good, the receiving station transmits a block count alteration request to restore the number of data blocks to be newly transmitted to a previous value. Meanwhile, as the transmitting station receives a retransmission request and its block count alteration request, the transmitting station transmits data blocks in accordance with it and data blocks changed (increased) in accordance with the block count alteration request in the same data packet.

In this manner, when communications conditions have deteriorated, newly transmitted data is more compressed. Although quality of reproduced data may fall, more data blocks can be retransmitted. This greatly reduces missing video or similar real time data and restrains occurrences of block noise. In contrast, when communications conditions have improved, newly transmitted data is less compressed, and new data blocks can be transmitted without lowering quality of reproduced data.

The transmitter device preferably includes:

new block selecting means for, when having received the retransmission request and the block count alteration request transmitted from the receiver device, selecting new data blocks to be transmitted in the same data packet as data blocks to be retransmitted in accordance with a retransmission request, in accordance with a block count alteration request; and

data block storage means for storing data blocks to be transmitted and reading data blocks in accordance with a retransmission request and data blocks selected by the new block selecting means as data blocks to be transmitted in the same data packet.

According to the arrangements, the selection of new blocks selects new data blocks to be transmitted in accordance with a block count alteration request. If reception conditions are poor at that time, a block count alteration request is transmitted from the transmitter device so as to restrict data blocks; new data blocks are therefore reduced. Besides, data blocks to be transmitted include those selected by the new block selecting means and stored in storage means. Further, the data read from the data storage means are the data blocks to be retransmitted and the data blocks selected by the new block selecting means and transmitted in the same data packet.

The communications method is preferably such that the transmitting station changes a length of a data packet in response to the block count alteration request from the receiving station. Meanwhile, the transmitter device is preferably such that the new block selecting means selects new data blocks so as to change a length of a data packet in response to the block count alteration request from the receiver device.

By the arrangement, when communications conditions have deteriorated, reducing the length of a data packet reduces the period of the communications cycle for the data packet, and accordingly increases the number of retransmissions of data blocks. Besides, when communications conditions are good, few data blocks are retransmitted; more new data blocks can be transmitted by increasing the length of the data packet.

Alternatively, the communications method is preferably such that the transmitting station does not change the length of the data packet in response to the block count alteration request from the receiving station. Meanwhile, the transmitter device is preferably such that the new block selecting means selects new data blocks so as to maintain the length of the data packet in response to the block count alteration request from the receiver device.

By the arrangement, unlike the previous arrangement, the length of the data packet remains unchanged in response to the block count alteration request; however, if the block count alteration request has increased the number of data blocks to be retransmitted, an additional bandwidth is secured for retransmission, by restricting the new data blocks that can be transmitted. If the block count alteration request has decreased the number of data blocks to be retransmitted, the number of new data blocks that can be transmitted increases, and a bandwidth is secured for transmission of more new data blocks.

The receiver device according to the present invention, to solve the problems, is a receiver device for receiving a data packet transmitted from a transmitter device, in which data is divided into one or more blocks, containing data blocks each of which has an error-correction code, and is characterized in that it includes:

error correction means for performing error correction on the data block on the basis of the error-correction code;

uncorrectable block identifying means for identifying error-uncorrectable data blocks on the basis of a result of error correction; and

request generating means for generating a retransmission request for the error-uncorrectable data blocks identified by the uncorrectable block identifying means and for generating a block count alteration request which changes a number of data blocks to be newly transmitted by the transmitter device in accordance with good/poor communications conditions based on a result of an error constant, to be transmitted to the transmitter device.

According to the arrangement, as the receiver device receives a data packet, the error correction means performs error correction on the data blocks in the data packet. Data blocks containing an uncorrectable error are identified by uncorrectable block identifying means on the basis of a result of the error correction. Then, the request generating means generates a retransmission request for uncorrectable data blocks and also generates a block count alteration request which changes the number of data blocks to be newly transmitted.

The block count alteration request is generated by the request generating means in accordance with good/poor communications conditions based on a result of an error constant; when communications conditions are poor, if by generating such a block count alteration request that the number of data blocks falls, the transmitter device decreases the number of new data blocks in accordance with the request, the number of data blocks that can be retransmitted increases accordingly. Besides, when communications conditions are good, by generating such a block count alteration request that the number of data blocks increases, the transmitter device increases the number of new data blocks in accordance with the request.

In this manner, by the receiver device generating a block count alteration request in accordance with good/poor communications conditions together with a retransmission request for data blocks, the transmitter device more compresses data to be newly transmitted when communications conditions have deteriorated; therefore, although quality of reproduced data falls, more data blocks can be retransmitted. This greatly reduces missing video or similar real time data and restrains occurrences of block noise. In contrast, when communications conditions have improved, the transmitter device less compresses newly transmitted data; therefore, new data blocks can be transmitted without lowering quality of reproduced data.

The receiver device is preferably such that the request generating means compares the number of errors per unit time to a predetermined, specified value to determine whether communications conditions are good or poor. By the arrangement, since there occur many errors under deteriorated communications conditions, communications conditions are determined to have deteriorated if the number of errors per unit time exceeds a specified value. Meanwhile, since there occur few errors under good communications conditions, communications conditions are determined to be good if the number of errors per unit time is below the specified value.

Alternatively, the receiver device is preferably such that the request generating means compares the total number of error-uncorrectable blocks in a received data packet to a predetermined, specified value to determine whether communications conditions are good or poor. By the arrangement, since there occur many error-uncorrectable data blocks identified by the uncorrectable block identifying means under deteriorated communications conditions, communications conditions are determined to have deteriorated if the total number of error-uncorrectable data blocks in a received data packet exceeds a specified value. Meanwhile, since there occur few error-uncorrectable data blocks under good communications conditions, communications conditions are determined to be good if the number of errors per unit time is below the specified value.

The communications system according to the present invention is characterized in that any of the previous transmitter devices and a plurality of any of the previous receiver devices. According to the communications system thus arranged, the transmission rate is suitably set in accordance with communications conditions; therefore, more data blocks are retransmitted by increasing the compression ratio for newly transmitted data under deteriorated communications conditions, whereas new data blocks can be transmitted without decreasing quality of reproduced data by decreasing the data compression ratio under improved communications conditions.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

As in the foregoing, according to the communications system of the present invention, when the number of error occurrences in a data block or the number of times a reproduction request is to be made in a data block exceeds a specified value due to, for example, deteriorated reception conditions, the cycle period is made shorter by increasing the data compression ratio. Therefore, the number of retransmissions of data blocks can be increased. This restrains missing data caused by data blocks that cannot be retransmitted. Therefore, the invention can be suitably used for real time data transmission.

1. A communications method where a data packet transmitted from a transmitting station is received at a receiving station using a data packet, in which data is divided into one or more blocks, containing data blocks each of which has an error-correction code, said system being characterized in that:
the receiving station transmits a retransmission request for an error-uncorrectable data block and transmits a block count alteration request which changes a number of data blocks to be newly transmitted in accordance with good/poor communications conditions on the basis of a result of error correction; and
the transmitting station transmits data blocks to be retransmitted in accordance with a retransmission request and new data blocks changed in accordance with a block count alteration request in the same data packet.

2. The communications method as set forth in claim 1, wherein
the transmitting station changes a transmission cycle of a data packet in response to the block count alteration request from the receiving station.

3. The communications method as set forth in claim 1, wherein
the transmitting station does not change a transmission cycle of a data packet in response to the block count alteration request from the receiving station.

4. A transmitter device for transmitting to a receiver device a data packet, in which data is divided into one or more blocks, containing data blocks each of which has an error-correction code, said device being characterized in that:
when having received a retransmission request for error-uncorrectable data blocks and a block count alteration request which changes a number of data blocks to be newly transmitted in accordance with good/poor communications conditions, transmitted from the receiver device, the transmitter device transmits data blocks to be retransmitted in accordance with a retransmission request and new data blocks changed in accordance with a block count alteration request in the same data packet.

5. The transmitter device as set forth in claim 4, comprising:
new block selecting means for, when having received the retransmission request and the block count alteration request transmitted from the receiver device, selecting new data blocks to be transmitted in the same data packet as data blocks to be retransmitted in accordance with a retransmission request, in accordance with a block count alteration request; and
data block storage means for storing data blocks to be transmitted and reading data blocks in accordance with a retransmission request and data blocks selected by the new block selecting means as data blocks to be transmitted in the same data packet.

6. The transmitter device as set forth in claim 5, wherein
the new block selecting means selects new data blocks so as to change a length of a data packet in response to the block count alteration request from the receiver device.

7. The transmitter device as set forth in claim 5, wherein
the new block selecting means selects new data blocks so as to maintain a length of a data packet in response to the block count alteration request from the receiver device.

8. A receiver device for receiving a data packet transmitted from a transmitter device, in which data is divided into one or more blocks, containing data blocks each of which has an error-correction code, said receiver device being characterized in that it comprises:
error correction means for performing error correction on the data block on the basis of the error-correction code;
uncorrectable block identifying means for identifying error-uncorrectable data blocks on the basis of a result of error correction; and
request generating means for generating a retransmission request for the error-uncorrectable data blocks identified by the uncorrectable block identifying means and for generating a block count alteration request which changes a number of data blocks to be newly transmitted by the transmitter device in accordance with good/poor communications conditions based on a result of an error constant, to be transmitted to the transmitter device.

9. The receiver device as set forth in claim 8, wherein
the request generating means compares a number of errors per unit time to a predetermined, specified value to determine whether communications conditions are good or poor.

10. The receiver device as set forth in claim 8, wherein
the request generating means compares a total number of error-uncorrectable blocks in a received data packet to a predetermined, specified value to determine whether communications conditions are good or poor.

11. A communications system, characterized in that it comprises:
a transmitter device as set forth in any one of claims 4 through 7; and
a receiver device as set forth in any one of claims 8 through 10.

12. The communications method as set forth in claim 1, wherein
the transmitting station changes a compression ratio for new data blocks in accordance with the block count alteration request.

13. The communications method as set forth in claim 2, wherein
the transmitting station changes a compression ratio for new data blocks in accordance with the block count alteration request.

14. The communications method as set forth in claim 3, wherein
the transmitting station changes a compression ratio for new data blocks in accordance with the block count alteration request.
